(19) United States
(12) Patent Application Publication
(10) Pub. No.: US 2026/0101816 A1
(43) Pub. Date: Apr. 9, 2026

(54) SEMICONDUCTOR DEVICE

(71) Applicant: SK hynix Inc., Icheon-si (KR)

(72) Inventor: Hyun Soo SHIN, Icheon-si (KR)

(21) Appl. No.: 19/033,316

(22) Filed: Jan. 21, 2025

(30) Foreign Application Priority Data
Sep. 5, 2024 (KR) 10-2024-0120882

(51) Int. Cl. H01L 23/00; H01L 25/07

(52) U.S. Cl. CPC H10W 90/00; H10W 72/931; H10W 72/934; H10W 80/312; H10W 80/327; H10W 90/792

(57) ABSTRACT

Embodiments of the present disclosure may provide a semiconductor device including a first chip including a first bonding pad and a first insulating layer, and a second chip disposed on the first chip, and including a second bonding pad bonded to the first bonding pad and a second insulating layer bonded to the first insulating layer, wherein a bonding interface between the first insulating layer and the second insulating layer includes a first step portion disposed around a bonding interface between the first bonding pad and the second bonding pad.

### CROSS-REFERENCE TO RELATED APPLICATION

The present application claims priority under 35 U.S.C. § 119(a) to Korean patent application number 10-2024-0120882 filed in the Korean Intellectual Property Office on Sep. 5, 2024, which is incorporated herein by reference in its entirety.

### TECHNICAL FIELD

The embodiments of the present disclosure relate to a semiconductor device with a hybrid bonding structure.

### BACKGROUND

The degree of integration of semiconductor devices continues to improve in order to achieve high capacity and miniaturization. As part of the effort to improve integration, a structure has been proposed in which components included in a semiconductor device are not manufactured on a single chip, but rather manufactured on multiple chips, and then the chips are joined using hybrid bonding.

### SUMMARY

Embodiments of the disclosure may provide a semiconductor device with improved reliability of hybrid bonding.

Embodiments of the disclosure may provide a semiconductor device including a first chip including a first bonding pad and a first insulating layer, and a second chip disposed on the first chip, and including a second bonding pad bonded to the first bonding pad and a second insulating layer bonded to the first insulating layer, wherein a bonding interface between the first insulating layer and the second insulating layer includes a first step portion disposed around a bonding interface between the first bonding pad and the second bonding pad.

Embodiments of the disclosure may provide a semiconductor device including a first chip including a first bonding pad and a first insulating layer having an opening exposing the first bonding pad, and a second chip including a second bonding pad bonded to the first bonding pad and a second insulating layer bonded to the first insulating layer, wherein the second insulating layer includes a protrusion having a side wall bonded to a side wall of the opening in the first insulating layer.

According to embodiments of the present disclosure, it is possible to improve the reliability of hybrid bonding by suppressing the formation of bridges between adjacent bonding pads and delamination of bonded chips.

### BRIEF DESCRIPTION OF THE DRAWINGS

FIG. 1 is a cross-sectional view of a semiconductor device according to an embodiment of the present disclosure.

FIG. 2 is an exploded view of a portion of FIG. 1.

FIGS. 3 to 5 are cross-sectional views of semiconductor devices according to embodiments of the present disclosure.

FIG. 6 is a perspective view of first and second bonding pads of FIG. 5.

FIG. 7 is a cross-sectional view of a semiconductor device according to an embodiment of the present disclosure.

FIG. 8 is a perspective view of first and second bonding pads of FIG. 7.

FIG. 9 is a cross-sectional view of a semiconductor device according to an embodiment of the present disclosure.

FIG. 10 is a perspective view of first and second bonding pads of FIG. 9.

FIG. 11 is a cross-sectional view of a semiconductor device according to an embodiment of the present disclosure.

FIG. 12 is a perspective view of first and second bonding pads of FIG. 11.

FIGS. 13 and 14 are cross-sectional views of semiconductor devices according to embodiments of the present disclosure.

FIG. 15 is a cross-sectional view of a semiconductor device according to an embodiment of the present disclosure.

### DETAILED DESCRIPTION

Hereinafter, various embodiments of the present disclosure will be described in detail with reference to accompanying drawings. The specific structural or functional descriptions of embodiments are provided as examples to explain the concepts disclosed herein. The embodiments or examples according to the concepts of the present disclosure may be implemented in various forms, and the scope of the present disclosure is not limited to the embodiments or examples described herein.

The same hatching shown throughout the drawings may indicate corresponding or identical areas in the drawings, and does not indicate materials associated with the corresponding areas.

When one element is described as being “connected” or “coupled” to another element, the elements may be directly connected or directly coupled, or may be connected or coupled through one or more intermediate elements between the elements. When two elements are described as being “directly connected” or “directly coupled,” one element is directly connected or directly coupled to the other element without any intermediate element between the two elements.

When one element is described as being disposed “over” or “under” another element, the elements may be in direct contact with each other, or an intermediate element may be disposed between the elements.

Terms such as “vertical,” “horizontal,” “upper,” “lower,”, “up”, “down”, “top,” “bottom,” “front,” “back,” “side,” “left and right,” “column,” “row,” “level,” and other relative spatial relationships or directions are used only for the purpose of ease of description or reference to the drawings, and are not limiting to any specific meaning. Other spatial relationships or directions not shown in the drawings or described in the specification are also possible within the scope of the present specification.

Terms such as “first” and “second” may be used to distinguish different elements and do not imply size, order, priority, quantity, or importance of the elements. For example, in some embodiments, a first element may be referred to as a second element, and in other embodiments, a second element may be referred to as a first element.

When an element included in embodiments in the present specification is described in the singular form, the element may be interpreted to include a plurality of elements performing the same or similar functions.

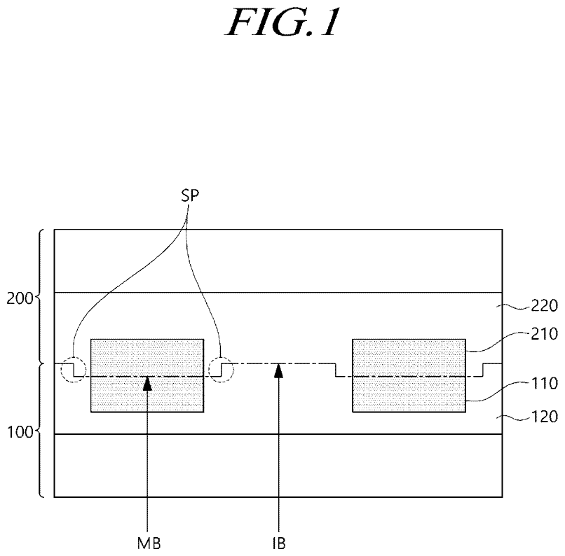

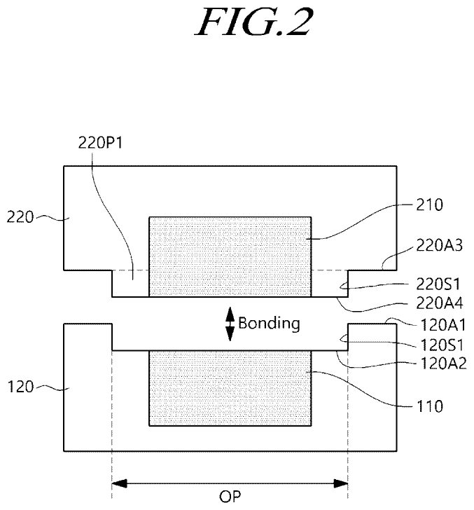

FIG. 1 is a cross-sectional view of a semiconductor device according to an embodiment of the present disclosure, and FIG. 2 is an exploded view of a portion of FIG. 1.

Referring to FIG. 1, a semiconductor device may include a first chip 100 and a second chip 200 that are hybrid bonded.

Each of the first chip 100 and the second chip 200 may include various types of electronic devices. The electronic devices may include, for example, a Metal Oxide Semiconductor Field Effect Transistor (MOSFET), a system Large Scale Integration (LSI), an image sensor such as a CMOS Imaging Sensor (CIS), a Micro Electro Mechanical System (MEMS), an active device, a passive device, etc.

In some embodiments, each of the first chip 100 and the second chip 200 may be at least one of a Dynamic Random Access Memory (DRAM) chip, a Static Random Access Memory (SRAM) chip, a flash memory chip, an Electrically Erasable and Programmable Read Only Memory (EEPROM) chip, a Phase change Random Access Memory (PRAM) chip, a Magnetic Random Access Memory (MRAM) chip, or a Resistive Random Access Memory (RRAM) chip.

The first chip 100 may include first bonding pads 110 and a first insulating layer 120. The first insulating layer 120 may surround each of the first bonding pads 110 and insulate adjacent first bonding pads 110 from each other.

The second chip 200 may include second bonding pads 210 and a second insulating layer 220. The second insulating layer 220 may surround each of the second bonding pads 210 and insulate adjacent second bonding pads 210 from each other.

The first and second bonding pads 110 and 210 may include a metal. The metal may include, for example, copper (Cu), aluminum (Al), silver (Ag), cobalt (Co), ruthenium (Ru), or an alloy thereof.

The first and second insulating layers 120 and 220 may include an oxide film and a nitride film. For example, the first and second insulating layers 120 and 220 may include silicon oxide (SiO2), carbon-doped silicon oxide (C-doped SiO2), silicon nitride (SiN), silicon carbon nitride (SiCN), a polymer, etc.

The first bonding pad 110 and the second bonding pad 210 may be bonded to each other to form a metal bonding interface MB. The metal bonding interface MB may be a boundary between the first bonding pad 110 and the second bonding pad 210, and the first bonding pad 110 and the second bonding pad 210 may be in contact with and bonded to each other at the metal bonding interface MB.

The first insulating layer 120 and the second insulating layer 220 may be bonded to each other to form an insulating bonding interface IB. The insulating bonding interface IB may be a boundary between the first insulating layer 120 and the second insulating layer 220, and the first insulating layer 120 and the second insulating layer 220 may be in contact with and bonded to each other at the insulating bonding interface IB.

The insulating bonding interface IB may have a step portion SP around the metal bonding interface MB. In one embodiment, the step portion SP may surround the metal bonding interface MB.

Referring to FIG. 2, in an exploded view of a metal bonding interface MB and surrounding step portions SP, the first insulating layer 120 may have an opening OP exposing the first bonding pad 110 on a second surface 120A2.

In an embodiment, the opening OP may have a larger area than the first bonding pad 110. The opening OP may have a larger width than the first bonding pad 110. The opening OP exposes the first bonding pad 110, the second surface 120A2 of the first insulating layer 120 around the first bonding pad 110, and a side wall 120S1 of the first insulating layer 120, which connects the second surface 120A2 and a first surface 120A1, which is offset from the second surface 120A2.

The second insulating layer 220 may include a protrusion 220P1 surrounding the second bonding pad 210. The second insulating layer 220 may have a third surface 220A3, and the protrusion 220P1 may protrude from the third surface 220A3 of the second insulating layer 220. The protrusion 220P1 may have a fourth surface 220A4 offset from the third surface 220A3, and a side wall 220S2 connecting the third surface 220A3 and the fourth surface 220A4.

An upper surface of the first bonding pad 110 and a lower surface of the second bonding pad 210 may be bonded to each other, thereby forming a metal bonding interface MB of FIG. 1. The first surface 120A1 of the first insulating layer 120 and the third surface 220A3 of the second insulating layer 220 may be bonded to each other, the second surface 120A2 of the first insulating layer 120 and the fourth surface 220A4 of the second insulating layer 220 may be bonded to each other, and the side wall 120S1 of the first insulating layer 120 and the side wall 220S2 of the second insulating layer 220 may be bonded to each other, thereby forming an insulating bonding interface IB of FIG. 1.

The metal included in the first and second bonding pads may be ionized, and the ions may migrate along the bonding interface between the first chip and the second chip to form a bridge between adjacent bonding pads.

According to an embodiment of the present disclosure, the insulating bonding interface IB has a step portion (SP in FIG. 1) around the metal bonding interface MB, so a distance of a migration path may increase. Furthermore, the structure of the migration path for the metal ions is more complicated. As a result, formation of a metal ion bridge between adjacent bonding pads is suppressed.

In addition, the insulating bonding interface (IB in FIG. 1) includes a step portion SP, and compared to a case where the insulating bonding interface is planar, the bonding area between the first chip 100 and the second chip 200 increases and the bonding strength between the first chip 100 and the second chip 200 may be improved. Consequently, delamination between the first chip 100 and the second chip 200 can be reduced.

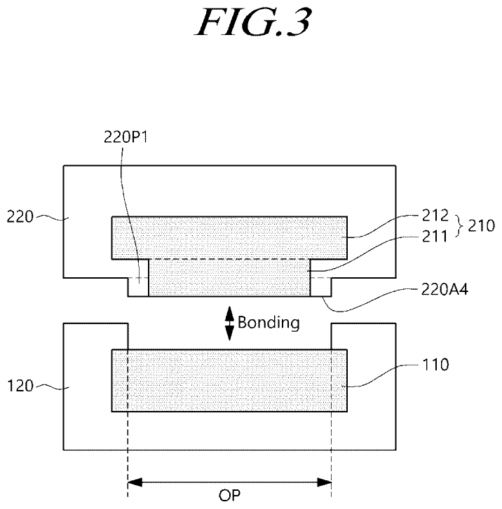

For the sake of simplicity, in the embodiments described below with reference to FIGS. 3 to 14, content overlapping with that described with reference to FIGS. 1 and 2 will be briefly described or omitted.

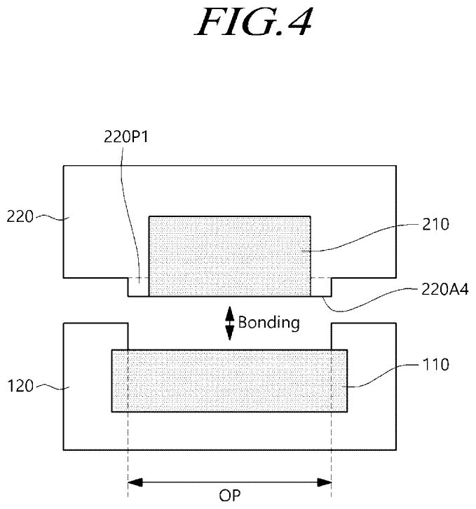

FIGS. 3 to 4 are cross-sectional views of semiconductor devices according to embodiments of the present disclosure.

Referring to FIG. 3, an opening OP in a first insulating layer 120 may have a smaller area than the first bonding pad 110 embedded in the first insulating layer 120. The opening OP may have a smaller width than the first bonding pad 110. The first insulating layer 120 may expose a center area of the first bonding pad 110 and cover an edge area of the first bonding pad 110.

The second bonding pad 210 may include a first portion 211 and a second portion 212 on the first portion 211. The first portion 211 of the second bonding pad 210 may have a smaller area relative to the opening OP of the first insulating layer 120. The first portion 211 of the second bonding pad 210 may have a smaller width relative to the opening OP. The second portion 212 of the second bonding pad 210 may have a larger area than the first portion 211 of the second bonding pad 210. The second portion 212 of the second bonding pad 210 may have a larger width than the first portion 211 of the second bonding pad 210.

The protrusion 220P1 of the second insulating layer 220 may surround the first portion 211 of the second bonding pad 210. The first portion 211 of the second bonding pad 210 may be bonded to the first bonding pad 110. The protrusion 220P1 of the second insulating layer 220 may vertically overlap with the first bonding pad 110, and a fourth surface 220A4 of the protrusion 220P1 may contact an upper surface of the first bonding pad 110.

Referring to FIG. 4, a second bonding pad 210 may have a smaller area than the opening OP of a first insulating layer 120. The second bonding pad 210 may have a smaller width than the opening OP.

A protrusion 220P1 of a second insulating layer 220 may surround a side surface of the second bonding pad 210. The second bonding pad 210 may be bonded to a first bonding pad 110. The protrusion 220P1 of the second insulating layer 220 may vertically overlap with the first bonding pad 110, and the fourth surface 220A4 of the protrusion 220P1 may contact an upper surface of the first bonding pad 110.

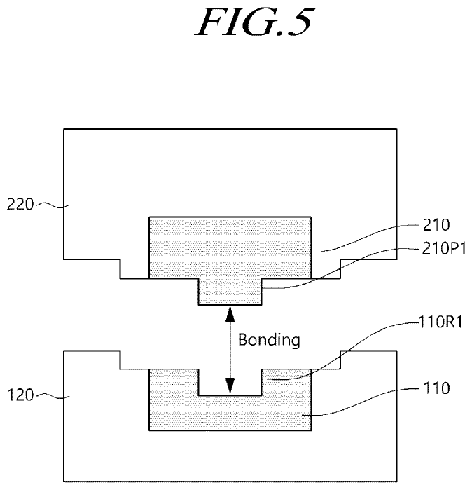

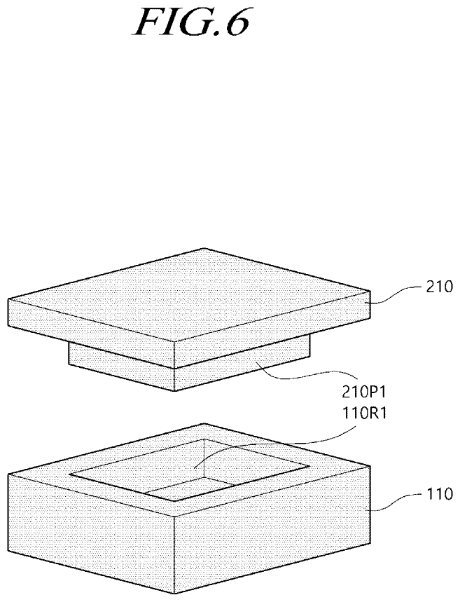

FIG. 5 is a cross-sectional view of a semiconductor device according to an embodiment of the present disclosure, and FIG. 6 is a perspective view of first and second bonding pads of FIG. 5.

Referring to FIGS. 5 and 6, a first bonding pad 110 may have a recessed portion 110R1 or a concavity from an upper surface, and a second bonding pad 210 may have a convex or protruding portion 210P1, which is coupled with the recessed portion 110R1 of the first bonding pad 110. The lower surface of the second bonding pad 210 and the lower surface of the first bonding pad 110 may be bonded to each other.

The recessed portion 110R1 may be disposed in a center area of the first bonding pad 110. The recessed portion 110R1 may be spaced apart from the first insulating layer 120, i.e., the surfaces of the recessed portion 110R1 may not contact the first insulating layer 120. Although the recessed portion 110R1 has a rectangular planar structure in FIGS. 5 and 6, the shape of the recessed portion 110R1 is not limited thereto.

The convex portion 210P1 may have a structure with a lower surface that is symmetrical to the surfaces common to recessed portion 110R1. The convex portion 210P1 may be disposed in a center area of the second bonding pad 210. The convex portion 210P1 may be spaced apart from the second insulating layer 220, i.e., the surfaces of the convex portion 210P1 may not contact the second insulating layer 220.

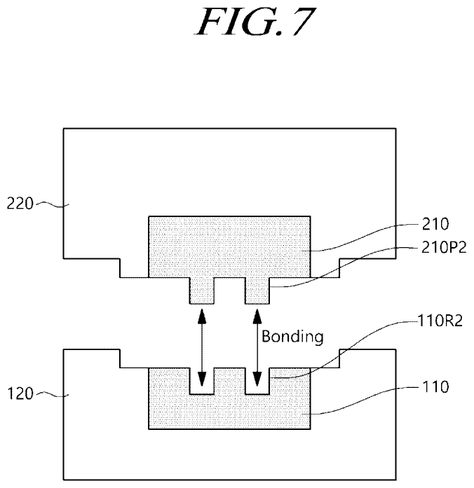

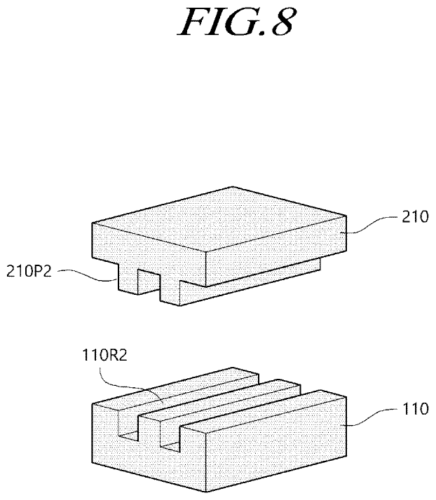

FIG. 7 is a cross-sectional view of a semiconductor device according to an embodiment of the present disclosure, and FIG. 8 is a perspective view of first and second bonding pads of FIG. 7.

Referring to FIGS. 7 and 8, a first bonding pad 110 with an upper surface may have a plurality of recessed portions 110R2 that are recessed from the upper surface, and a second bonding pad 210 may have protrusions 210P2, which have lower surfaces that are coupled with the recessed portions 110R2 of the first bonding pad 110.

A recessed portion 110R2 may have a line shape extending in one direction. In an embodiment, the recessed portion 110R2 may extend across the first bonding pad 110, and both ends of the recessed portion 110R2 may be connected to the first insulating layer 120.

The protrusion 210P2 may have a structure symmetrical to the recessed portion 110R2. The protrusion 210P2 may cross the second bonding pad 210, and both ends of the protrusion 210P2 may be connected to the second insulating layer 220.

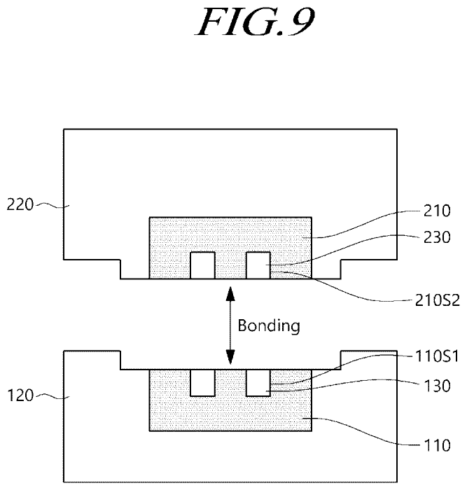

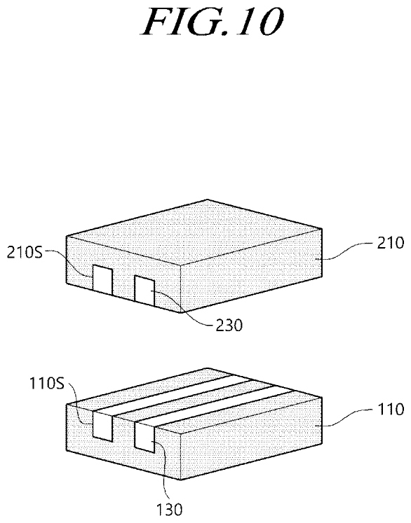

FIG. 9 is a cross-sectional view of a semiconductor device according to an embodiment of the present disclosure, and FIG. 10 is a perspective view of first and second bonding pads of FIG. 9.

Referring to FIGS. 9 and 10, a first bonding pad 110 may have a first slit 110S1 on an upper surface. The first slit 110S1 may be filled with a first insulating pattern 130. In an embodiment, the first slit 110S1 may extend across the first bonding pad 110 in one direction, and both ends of the first slit 110S may be connected to a first insulating layer 120. Both ends of the first insulating pattern 130 may be in contact with the first insulating layer 120.

A second bonding pad 210 may have a second slit 210S2 on a lower surface. The second slits 210S2 may have a structure symmetrical to the first slits 110S1.

The second slits 210S2 may be filled with a second insulating pattern 230. In an embodiment, the second slit 210S2 may extend across the second bonding pad 210 in one direction, and both ends of the second slit 210S2 may be connected to a second insulating layer 220. Both ends of the second insulating pattern 230 may be in contact with the second insulating layer 220.

The first and second insulating patterns 130 and 230 may include an oxide film and a nitride film. For example, the first and second insulating patterns 130 and 230 may include silicon oxide (SiO2), carbon-doped silicon oxide (C-doped SiO2), silicon nitride (SiN), silicon carbon nitride (SiCN), a polymer, etc.

The first insulating pattern 130 and the second insulating pattern 230 may vertically overlap each other, and an upper surface of the first insulating pattern 130 and a lower surface of the second insulating pattern 230 may be bonded to each other.

The bonding strength between the first insulating pattern 130 and the second insulating pattern 230 may be greater than the bonding strength between the first bonding pad 110 and the second bonding pad 210. The increased bonding strength between the first insulating pattern 130 and the second insulating pattern 230 improves the overall adhesive strength between the first chip 100 and the second chip 200, so delamination between the first chip 100 and the second chip 200 can be suppressed or reduced.

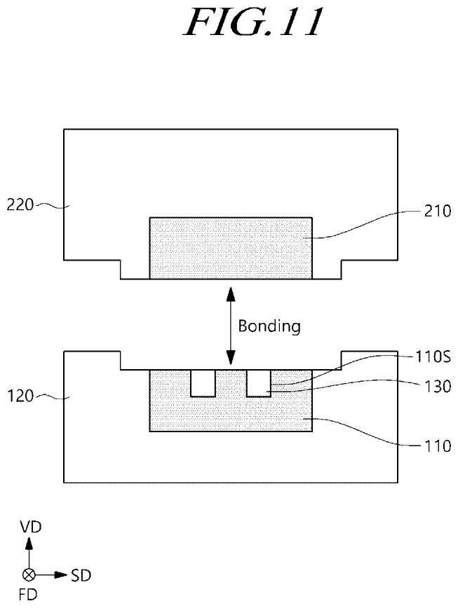

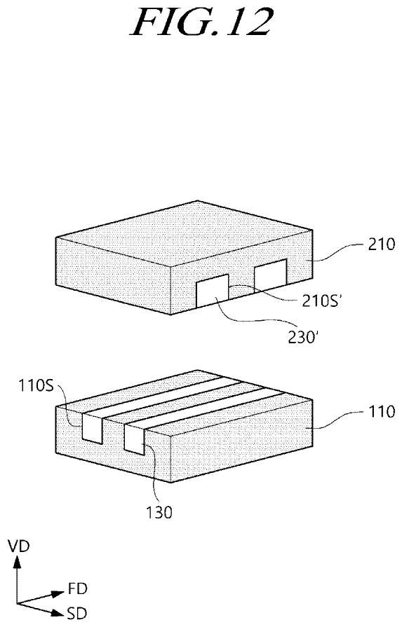

FIG. 11 is a cross-sectional view of a semiconductor device according to an embodiment of the present disclosure, and FIG. 12 is a perspective view of first and second bonding pads of FIG. 11.

Referring to FIG. 11 and FIG. 12, a first bonding pad 110 may have a first slit 110S on an upper surface. The first slit 110S may have a line shape extending in a first direction FD. The first slit 110S may be filled with a first insulating pattern 130. In an embodiment, the first slit 110S may extend across the first bonding pad 110 in the first direction FD, and both ends of the first slit 110S may be connected to a first insulating layer 120. Both ends of the first insulating pattern 130 may be in contact with the first insulating layer 120.

A second bonding pad 210 may have a second slit 210S′ on a lower surface. The second slit 210S′ may have a line shape extending in a second direction SD intersecting the first direction FD. The second slit 210S′ may be filled with a second insulating pattern 230′.

In an embodiment, the second slit 210S′ may extend across the second bonding pad 210 in the second direction SD, and both ends of the second slit 210S′ may be connected to a second insulating layer 220. Both ends of the second insulating pattern 230′ may be in contact with the second insulating layer 220.

The first insulating pattern 130 and the second insulating pattern 230′ may intersect each other and vertically overlap with each other at an intersection point. At the intersection point, the first insulating pattern 130 and the second insulating pad 230′ may be bonded to each other.

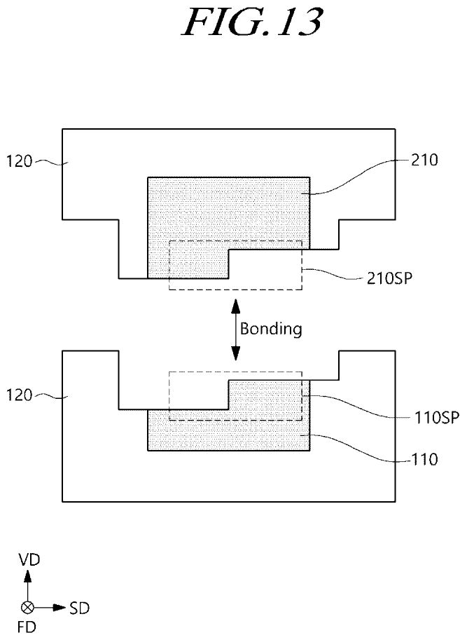

FIG. 13 is a cross-sectional view of a semiconductor device according to an embodiment of the present disclosure.

Referring to FIG. 13, a first bonding pad 110 may have a first step portion 110SP on an upper surface. A second bonding pad 210 may have a second step portion 210SP on a lower surface.

The first step portion 110SP and the second step portion 210SP may have structures that are symmetrical to each other. For example, the height difference between horizontal surfaces of a protrusion and a recessed portion of the second step portion 210SP may be the same as the height difference between horizontal surfaces of a protrusion and a recessed portion of the first step portion 110SP. The protrusion of the first step portion 110SP may be bonded to the recessed portion of the second step portion 210SP, and the recessed portion of the first step portion 110SP may be bonded to the protrusion of the second step portion 210SP.

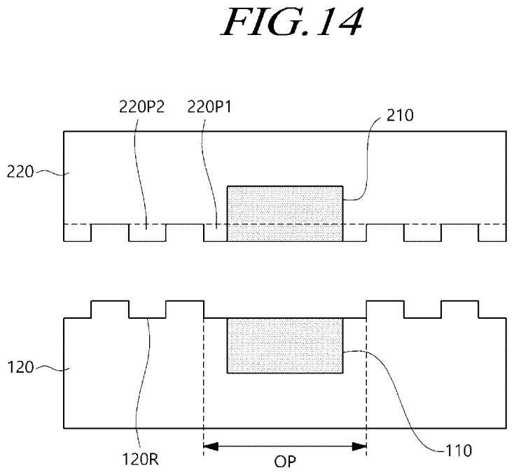

FIG. 14 is a cross-sectional view of a semiconductor device according to an embodiment of the present disclosure.

Referring to FIG. 14, a first insulating layer 120 may have a recessed portion 120R around an opening OP. A second insulating layer 220 may have a convex portion 220P2 protruding from a lower surface of a recessed portion 120R. The convex portion 220P2 may be disposed around the protrusion 220P1.

By configuring a recessed portion 120R and a convex portion 220P2, the length of a migration path for metal ions may be further increased, and the structure of the migration path may be further complicated. Accordingly, the formation of bridges between adjacent bonding pads may be further suppressed.

The semiconductor devices according to the embodiments described above may be a vertical NAND flash memory device. However, in other embodiments, the semiconductor device may be multi-die, chiplet type semiconductor devices.

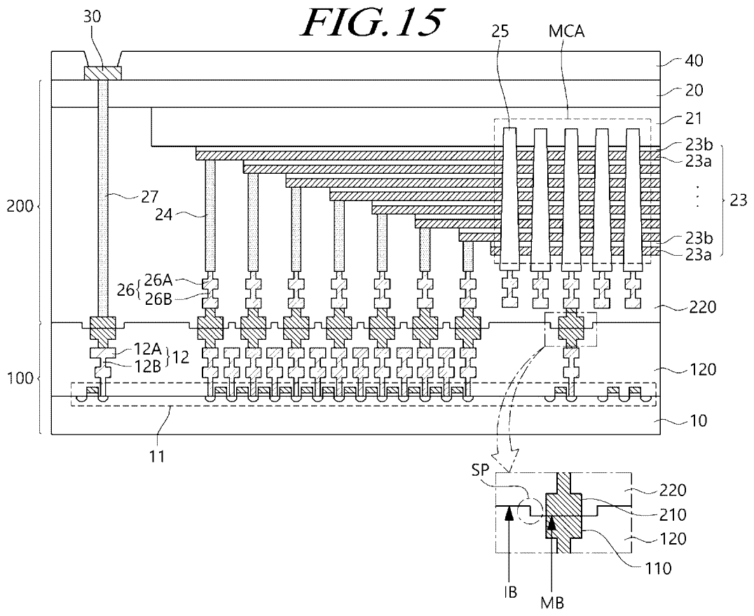

FIG. 15 is a cross-sectional view of a semiconductor device according to an embodiment of the present disclosure. FIG. 15 illustrates a semiconductor device as a vertical NAND flash memory.

Referring to FIG. 15, a first chip 100 may be a peripheral circuit chip, and a second chip 200 may be a memory chip.

The first chip 100 may include a first substrate 10, a peripheral circuit 11, a first bonding pad 110, a first insulating layer 120, and a first wiring structure 12.

The peripheral circuit 11 may be disposed on the first substrate 10. The peripheral circuit 11 may control the operation of a memory cell array MCA. The peripheral circuit 11 may include, for example, a row decoder, a page buffer circuit, control logic, and a voltage generator, but the circuit is not limited thereto. The peripheral circuit 11 may include a plurality of individual elements. The individual elements may include transistors.

The first insulating layer 120 may be disposed on the first substrate 10, and may cover the peripheral circuit 11. The first bonding pad 110 may be disposed in the first insulating layer 120. An upper surface of the first bonding pad 110 may be exposed to an upper surface of the first insulating layer 120.

The first wiring structure 12 may electrically connect the peripheral circuit 11 to a first bonding pad 110. The first wiring structure 12 may include a plurality of first conductive lines 12A arranged at different vertical levels within the first insulating layer 120 and a first via 12B vertically extending within the first insulating layer 120. The first via 12B may electrically connect the plurality of first conductive lines 12A that are arranged at different vertical levels.

The second chip 200 may include an insulating structure 20, a conductive plate 21, a gate stack 23, a contact 24, a cell plug 25, a second wiring structure (26), a second bonding pad 210, and a second insulating layer 220.

The insulating structure 20 may have a lower surface and an upper surface facing each other. The conductive plate 21 may be disposed on a lower surface of the insulating structure 20. The conductive plate 21 may include a metal material, a semiconductor material, or a combination thereof.

The gate stack 23 may include a plurality of gate electrode layers 23a and a plurality of interlayer insulating layers 23b alternately stacked on the lower surface of the conductive plate 21. The gate electrode layers 23a may include a conductive material. For example, the gate electrode layers 23a may include tungsten (W). The interlayer insulating layers 23b may include silicon oxide.

The gate electrode layers 23a may include word lines. The gate electrode layers 23a may further include at least one source select line and at least one drain select line. The gate electrode layers 23a may extend in different lengths to form a step structure. Contacts 24 may be connected on the step structure to the gate electrode layers 23a.

A plurality of cell plugs 25 may extend vertically through the gate stack 23 to the conductive plate 21.

Each of the cell plugs 25 may include a channel layer and a cell gate insulating layer. The cell gate insulating layer may have a straw or cylinder shell shape that surrounds the outer wall of the channel layer. The cell gate insulating layer may include a tunnel insulating film, a charge storage film, and a blocking film that are sequentially laminated from the outer wall of the channel layer. In some embodiments, the cell gate insulating layer may have an Oxide-Nitride-Oxide (ONO) stacked structure in which an oxide film, a nitride film, and an oxide film are sequentially stacked. Memory cells may be configured in portions where word lines surround the cell plug 25. A source select transistor may be configured in a portion where a source select line surrounds the cell plug 25. A drain select transistor may be configured in a portion where a drain select line surrounds the cell plug 25. A drain select transistor, a plurality of memory cells, and a source select transistor arranged along one cell plug 25 may constitute one cell string. There may be provided a plurality of cell strings corresponding to a plurality of cell plugs 25. The plurality of cell strings may constitute the memory cell array MCA.

The second wiring structure 26 may include a plurality of second conductive lines 26A arranged at different vertical levels within the second insulating layer 220 and a plurality of second vias 26B extending vertically within the second insulating layer 220. The plurality of second vias 26B may electrically connect between the plurality of second conductive lines 26A arranged at different vertical levels.

Each of the contacts 24 and the cell plugs 25 may be connected to the second bonding pad 210 through the second wiring structure 26.

The semiconductor device may further include an external connection pad 30 disposed on the insulating structure 20 of the second chip 200, and a passivation layer 40 disposed on the insulating structure 20 and having an opening exposing the external connection pad 30. The external connection pad 30 may be connected to the second bonding pad 210 through a through via 27. The through via 27 may vertically penetrate the insulating structure 20 and the second insulating layer 220 to form a vertical connection wiring electrically connecting the external connection pad 30 and the second bonding pad 210.

The first bonding pad 110 of the first chip 100 and the second bonding pad 210 of the second chip 200 may be bonded to each other to form a metal bonding interface MB. The first insulating layer 120 of the first chip 100 and the second insulating layer 220 of the second chip 200 may be bonded to each other to form an insulating bonding interface IB. The insulating bonding interface IB may have a step portion SP that surrounds the metal bonding interface MB.

Although a semiconductor device of FIG. 15 includes one memory chip and one peripheral circuit chip, embodiments are not limited thereto. As another example, a semiconductor device may include two or more memory chips or two or more peripheral circuit chips. As another example, at least one of the semiconductor chips included in the semiconductor device may have a Peri-Under-Cell (PUC) structure including a peripheral circuit area and a memory cell area built up on the peripheral circuit area.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical ideas of this disclosure but to explain the technical ideas of this disclosure, the scope of the technical ideas of this disclosure is not limited by these embodiments. The protection scope of this disclosure should be interpreted by the claims below, and all technical ideas within the equivalent scope should be interpreted as being included in the scope of the rights of this disclosure.

What is claimed is:

1. A semiconductor device comprising:
a first chip including a first bonding pad and a first insulating layer; and
a second chip disposed on the first chip, and including a second bonding pad bonded to the first bonding pad and a second insulating layer bonded to the first insulating layer,
wherein a bonding interface between the first insulating layer and the second insulating layer includes a first step portion disposed around a bonding interface between the first bonding pad and the second bonding pad.

2. The semiconductor device of claim 1, wherein the first step portion is configured to surround a periphery of the bonding interface between the first bonding pad and the second bonding pad.

3. The semiconductor device of claim 1, wherein the first bonding pad further includes a recessed portion,
wherein the second bonding pad further includes a convex portion coupled to the recessed portion.

4. The semiconductor device of claim 1, further comprising:
a first insulating pattern filling a first slit provided on a surface of the first bonding pad bonded to the second bonding pad; and
a second insulating pattern filling a second slit provided on a surface of the second bonding pad bonded to the first bonding pad.

5. The semiconductor device of claim 4, wherein the first insulating pattern and the second insulating pattern are vertically overlapped with each other and are bonded to each other.

6. The semiconductor device of claim 4, wherein the first insulating pattern and the second insulating pattern intersect each other and are bonded to each other at an intersection point.

7. The semiconductor device of claim 1, wherein the first insulating layer further includes a recessed portion disposed around the first step portion, and the second insulating layer further includes a convex portion coupled with the recessed portion.

8. The semiconductor device of claim 1, wherein the first bonding pad further includes a second step portion, and the second bonding pad further includes a third step portion coupled with the second step portion.

9. A semiconductor device comprising:
a first chip including a first bonding pad and a first insulating layer having an opening exposing the first bonding pad; and
a second chip including a second bonding pad bonded to the first bonding pad and a second insulating layer bonded to the first insulating layer,
wherein the second insulating layer includes a protrusion having a side wall bonded to a side wall of the opening in the first insulating layer.

10. The semiconductor device of claim 9, wherein the second bonding pad includes a first portion bonded to the first bonding pad, and a second portion disposed on the first portion,
wherein the first portion has a area smaller than the opening.

11. The semiconductor device of claim 10, wherein the protrusion of the second insulating layer is configured to surround a side surface of the first portion of the second bonding pad.

12. The semiconductor device of claim 9, wherein the second bonding pad has a smaller area than the first bonding pad.

13. The semiconductor device of claim 9, wherein the opening has a larger area than the first bonding pad.

14. The semiconductor device of claim 9, wherein the first bonding pad further includes a recessed portion, and the second bonding pad further includes a convex portion coupled with the recessed portion.

15. The semiconductor device of claim 9, wherein the first insulating layer further includes a recessed portion disposed around the opening, and the second insulating layer further includes a convex portion coupled with the recessed portion.

16. The semiconductor device of claim 9, further comprising:
a first insulating pattern filling a first slit arranged on a surface of the first bonding pad; and
a second insulating pattern filling a second slit arranged on a surface of the second bonding pad.

17. The semiconductor device of claim 16, wherein the first insulating pattern and the second insulating pattern vertically overlap with each other and are bonded to each other.

18. The semiconductor device of claim 16, wherein the first insulating pattern and the second insulating pattern intersect with each other and are bonded to each other at an intersection point.

19. The semiconductor device of claim 9, wherein the first bonding pad further includes a first step portion, and the second bonding pad further includes a second step portion coupled with the first step portion.
